(19) United States
(12) Patent Application Publication
(10) Pub. No.: US 2025/0308951 A1
(43) Pub. Date: Oct. 2, 2025

(54) DIE TO WAFER BONDING METHOD AND APPARATUS WITH THERMAL CONTACTLESS DIE SHAPE CONTROL

(71) Applicant: Tokyo Electron Limited, Tokyo (JP)

(72) Inventors: Anton DEVILLIERS, Albany, NY (US); Hans D’ACHARD, Albany, NY (US); Helger van HALEWIJN, Albany, NY (US); Eric KOSTERS, Albany, NY (US); Sven PEKELDER, Albany, NY (US); David CONKLIN, Albany, NY (US); Anthony SCHEPIS, Albany, NY (US); David POWER, Albany, NY (US)

(73) Assignee: Tokyo Electron Limited, Tokyo (JP)

(21) Appl. No.: 18/622,713

(22) Filed: Mar. 29, 2024

(51) Int. Cl. H01L 21/67; H01L 21/683; H01L 23/00

(52) U.S. Cl. CPC H01L 21/67115; H01L 21/67248; H01L 21/6838; H01L 24/80; H01L 2224/80895; H01L 2224/80896

(57) ABSTRACT

Aspects of the present disclosure provide an apparatus that heats a semiconductor structure while holding the semiconductor structure. For example, the apparatus can include a semiconductor structure holding device that is configured to hold the semiconductor structure. The apparatus can also include a light projection device that is configured to generate a certain pattern of light. The light projection device can be integrated with the semiconductor structure holding device such that when the semiconductor structure holding device is holding the semiconductor structure, the certain pattern of light generated by the light projection device is projected onto the semiconductor structure holding device and a corresponding certain pattern of heat is generated and transferred through the semiconductor structure holding device and applied to the semiconductor structure, in order to correct the shape and size of the semiconductor structure.

### FIELD OF THE INVENTION

The present disclosure relates to semiconductor fabrication, and, more particularly, to die to die/wafer bonding method and apparatus with thermal contactless die shape control.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

A typical semiconductor device can be comprised of over 70 individual layers. Each level requires multiple process steps including, but not limited to, thin film deposition, lithography and etches to form the desired structures. Non-uniform wafer stresses induced through these operations result from the patterning of thin films and are amplified via multiple temperature cycling processes, fundamentally distorting the wafer grid and creating unique wafer shapes throughout the entire integration. Current die to die-wafer bonding methods cannot handle (on an industrial scale) other distortions than just magnification, whereas the actual distortions due to lithography and warping include also dipole, quadrupole and higher order terms. There is no reliable solution to match the shape and side of a (distorted) die to the receiving bonding location.

### SUMMARY

Aspects of the present disclosure provide an apparatus that heats a semiconductor structure while holding the semiconductor structure. For example, the apparatus can include a semiconductor structure holding device that is configured to hold the semiconductor structure. The apparatus can also include a light projection device that is configured to generate a certain pattern of light. The light projection device can be integrated with the semiconductor structure holding device such that when the semiconductor structure holding device is holding the semiconductor structure, the certain pattern of light generated by the light projection device is projected onto the semiconductor structure holding device and a corresponding certain pattern of heat is generated and transferred through the semiconductor structure holding device and applied to the semiconductor structure.

In an embodiment, the semiconductor structure holding device can be a gripper. For example, the gripper can be a vacuum gripper. In an embodiment, the gripper can include aluminum nitride (AlN). In another embodiment, the gripper can include siliconized silicon carbide (SiSiC).

In an embodiment, the light projection device can include a plurality of light projection units that are controlled to generate light independently. For example, the light projection units can be arranged in a matrix. In an embodiment, at least one of the light projection units can include one or more laser devices. In another embodiment, at least one of the light projection units can include a digital light processor. In some embodiment, at least one of the light projection units can include an array of light pipes. In various embodiments, the at least one of the light projection units can further include a temperature sensor that is configured to sense a temperature of the at least one of the light projection units. In other embodiments, the light projection device can further include a heat sink that is thermally coupled to the light projection units.

Aspects of the present disclosure also provide a method that can bond a first semiconductor structure to a second semiconductor structure, while the shape of the first semiconductor structure is fixed in time by a sacrificial carrier substrate. For example, the method can include generating a certain pattern of light such that a corresponding certain pattern of heat is applied to a first semiconductor structure to shape the first semiconductor structure and bonding a first surface of the shaped first semiconductor structure to a carrier substrate. In an embodiment, the carrier substrate can have a lower thermal conductivity than the first semiconductor structure.

In an embodiment, the carrier substrate can include silicon oxide (SiOₓ) or silicon nitride (SiNₓ). In another embodiment, the method can also include forming a light absorption layer on a first semiconductor structure, wherein generating the certain pattern of light includes generating the certain pattern of light such that the corresponding certain pattern of heat is applied to the light absorption layer formed on the first semiconductor structure to shape the first semiconductor structure.

In an embodiment, the method can further include bonding a second surface of the shaped first semiconductor structure to a second semiconductor structure and removing the carrier substrate. In another embodiment, the method can further include providing a plurality of light projection units that are configured to generate light independently and controlling the light projection units to generate the certain pattern of light. For example, each of the light projection units can generate heat that causes a corresponding displacement field to the semiconductor structure, and the certain pattern of heat is applied based on a combination of the displacement fields caused by the heating units. In some embodiments, the method can further include providing a semiconductor structure holding device that is configured to hold the first semiconductor structure and controlling the semiconductor structure holding device to hold the first semiconductor structure.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1A shows a top view of a semiconductor structure with no distortion;

FIGS. 1B-1F show top views of semiconductor structures with various distortion;

FIG. 2 is a functional block diagram of an exemplary wafer processing system for controlling and adapting the dimension of a die that may be distorted and bonding the shaped die to a target die (or wafer) according to some embodiments of the present disclosure;

FIG. 3 is a flow chart of an exemplary method that bonds a shaped die to a target semiconductor structure, e.g., a wafer or die, with the shape of the shaped die being fixed in time, according to some embodiments of the present disclosure;

FIGS. 4A-4G are schematic diagrams illustrating the wafer processing system implementing the method according to some embodiments of the present disclosure;

FIG. 5A is a schematic diagram and a side view of an exemplary apparatus that includes a light projection device and a gripper that are integrated with each other according to some embodiments of the present disclosure;

FIG. 5B is a side view of the apparatus;

FIGS. 6A and 6B are a side view and a circuit diagram of an exemplary light projection device, respectively, according to some embodiments of the present disclosure; and

FIG. 7 illustrates how light and heat generated by each of a plurality of light projection units of the light projection device that are arranged in a matrix distorts or causes displacement to a die according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

As sizes of semiconductor devices scale according to Moore's law, the use of advanced packaging, e.g., three-dimensional (3D) vertical stacking based on hybrid bonding, is becoming the next step to increase performance of such a semiconductor device. High density interconnection between two or more 3D vertically stacked semiconductor devices ensures high performance in combination with a smaller form factor. A reliable interconnection between two vertically stacked semiconductor devices requires a position accuracy of the interconnects in the nanometer range. Unlike overlay in an optical system, where stage and lens manipulation can be used to improve overlay, in hybrid bonding distortion of the semiconductor device has to be controlled and corrected by dimensional shaping of the semiconductor device. With the shrinking size of microelectronics, also the electrical contact pads are shrinking, and, at the same time, the number of contact pads is increasing due to rising circuit complexity. One way to cope with this development is to do direct die to die bonding, for instance, memory to logic. With the coming generations of microchips, also these contact pads become so small that conventional methods are insufficient to secure that all contact pads of both dies are lined up correctly for a functional end result.

The present disclosure provides means to control and adapt the dimension of a (singulated) die using thermal expansion of the material thereof by thermal manipulation introduced by a heating matrix. In an embodiment, the required thermal XY pattern generated by the heating matrix can be calculated or estimated to deform the die in XY to match the receiving bond location. In another embodiment, an intermediate step can be introduced where the shaped die can be placed (e.g., with its backside surface) on a sacrificial carrier substrate that is made of, for example, silicon oxide (SiOₓ), SiOxiNitride and silicon nitride (SiNₓ), that freezes the shape of the die mechanically at ambient temperature and conditions, then the stack of the shaped die and the sacrificial carrier can be placed on a target die (or wafer) at ambient conditions, and the sacrificial carrier can then be removed, e.g., by polish or laser process.

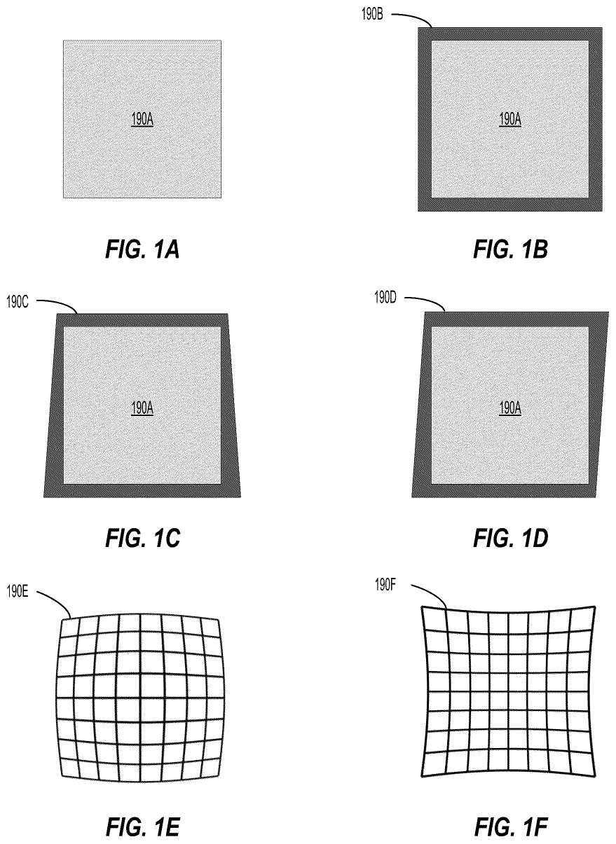

FIG. 1A shows a top view of a semiconductor structure (or a semiconductor device, e.g., a wafer or die) 190A with no distortion. As more layers (or tiers) of semiconductor components and signal wiring structures are formed, the semiconductor structure 190A may become a semiconductor structure with distortion. For example, during the formation of the semiconductor components and the signal wiring structures, the semiconductor structure 190A may become a semiconductor structure 190B that has symmetrically scaled distortion (as shown in FIG. 1B), become a semiconductor structure 190C that has trapezoidal distortion (as shown in FIG. 1C), or become a semiconductor structure 190D that has shear distortion (as shown in FIG. 1D). The semiconductor structure 190A may also become a semiconductor structure that has symmetrically radial distortion. For example, the semiconductor structure 190A may become a semiconductor structure 190E that has barrel (negative) distortion (as shown in FIG. 1E) or become a semiconductor structure 190F that has pincushion (positive) distortion (as shown in FIG. 1F). Aspects of the present disclosure provide methods and apparatuses that can correct at least these distorted semiconductor structures 190B-190F via thermal expansion control.

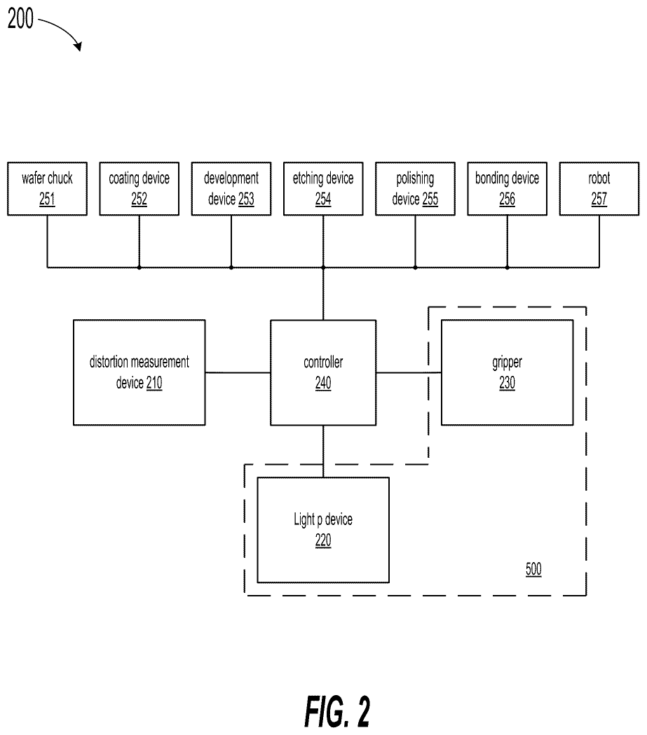

FIG. 2 is a functional block diagram of an exemplary wafer processing system 200 for controlling and adapting the dimension, e.g., XY dimension, of a die that may be distorted and bonding the shaped die to a target die (or wafer) according to some embodiments of the present disclosure. In an embodiment, the distorted die may be obtained by singulating a distorted semiconductor structure, e.g., the semiconductor structures 190B-190F. Typical die sizes are 26 mm×33 mm in width and length in maximum, with a typical thickness of 800 microns and thinner, even down to for instance 50 microns. Bulk or carrier material can be silicon, but also for instance silicon oxide (SiOₓ) or silicon nitride (SiNₓ). The active circuits, e.g., the semiconductor components and the signal wiring structures, can be embedded in this bulk or carrier, or placed on top of this bulk or carrier die.

The wafer processing system 200 can include metrology equipment, e.g., a (XY) distortion measurement device 210. In an embodiment, the distortion measurement device 210 can be configured to measure a semiconductor structure that may be distorted (e.g., the semiconductor structures 190B-190F) and a distorted die that may be obtained by singulating the semiconductor structure, to identify a distortion measurement, e.g., an XY distortion measurement, of the semiconductor structure. In an embodiment, the distortion measurement device 210 can use optical (e.g., using a scanning laser technique) (e.g., optical interferometers), acoustic and other mechanisms (e.g., capacitive sensors) to measure the XY deviations of the semiconductor structure and store the XY deviations by (x, y) coordinates to identify the XY distortion measurement of the semiconductor structure. In some embodiments, the XY distortion measurement can include raw distortion data or be represented as a distortion signature with relative values.

The wafer processing system 200 can further include a light projection device 220 that is configured to project a certain pattern of light (thus generating a corresponding certain pattern of heat) (or a certain thermal XY pattern or profile) according to the XY distortion measurement of the semiconductor structure, e.g., the distorted die. As a result, a certain pattern of heat that corresponds to the certain pattern of light can be applied to the distorted die to deform, correct or modify the XY distortion of the distorted die. For example, the light projection device 220 can be a laser device (e.g., scanning laser, direct laser write, etc.), a digital light processor (DLP), an array of light pipes, etc. In some embodiments, the light projection device 220 can include a plurality of light projection units that have an arrangement corresponding to the certain pattern of light and are controlled independently to project different intensity ranges of light (accordingly, generating different temperature ranges of heat). For example, the light projection units can be arranged in a matrix. Accordingly, the distorted die can be heated in different regions that correspond to the certain pattern of light and the certain pattern of heat, both of which correspond to the XY distortion measurement of the distorted die, and the (XY) dimension of the distorted die can thus be corrected or modified. For the light projection device 220, various wavelengths have different penetration depths and absorption reflection couplings to the die or the layering or the die. In an embodiment, a defined layer can be deposited on the backside surface of the die which is optimized to a specific absorption for a specific wavelength. This absorption layer can be removed after attachment of the die to the wafer. Main issue here is that continuous heating will result in ever rising of the temperature, and all locally deposited heat will flow away laterally, causing the distortion pattern to be of a dynamic nature. Also, a (single) pulsed deposition will only result in a shortly lived distorted shape. This limits the available time for placement and bonding before the shape dissipates (fades). A way around this is to create a balance between heating and cooling. Light energy can be added in the center of a cell, where as cooling-contact can remove the heat at the edge of a cell. The heat resistance from center to edge will result in a stable temperature difference and local expansion of the cell.

The wafer processing system 200 can further include a semiconductor structure holding device (e.g., a gripper, a clamper, and so on) 230 that is configured to pick up, hold and grip a wafer (or a die), e.g., a semiconductor structure. For example, the gripper 230 can be a vacuum gripper 230. In operation, a negative pressure can be created inside a hose and a vacuum head to cause suction cups or foam pads to stick to the surface of the wafer.

In an embodiment, the wafer processing system 200 can further include other components, such as a wafer chuck 251 for a wafer to be placed thereon, a coating device 252 configured to coat a working surface and/or backside surface of the wafer with a photosensitive material (e.g., a photoresist layer) or a heat sensitive material, a development device 253 configured to develop a latent pattern in the photoresist layer, an etching device 254 configured to use plasma or vapor-phase etching or wet etching to etch the photoresist layer, a polishing device 255 configured to polish (e.g., chemical-mechanical polishing, CMP) a semiconductor structure, and a bonding device 256 configured to bonding a die or wafer to a wafer or die that is placed on the wafer chuck 251. In some embodiments, the wafer processing system 200 can further include a robot 257 that can be coupled to the gripper 230 and configured to transfer the wafer or die, which is gripped by the gripper 230, among different treatment modules, where the distortion measurement device 210, the light projection device 220, the wafer chuck 251, the coating device 252, the development device 253, the etching device 254, the polishing device 255 and/or the bonding device 256 may be installed, for various processing. In an embodiment, due to variations in the surface layering of the die, a light absorption layer may be needed to ensure correct in-coupling of the light energy into the die.

In an embodiment, the wafer processing system 200 can further include a controller 240 that is coupled to the distortion measurement device 210, the light projection device 220, the gripper 230, the wafer chuck 251, the coating device 252, the development device 253, the etching device 254, the polishing device 255, the bonding device 256 and the robot 257 and configured to control the operations thereof. For example, the controller 240 can be configured to control the gripper 230 to grip a semiconductor structure (e.g., a distorted die), to control the distortion measurement device 210 to measure the semiconductor structure (e.g., the distorted die) to identify the XY distortion measurement of the distorted die, to control the light projection device 220 to project to the distorted die a certain pattern of light (equivalently generating a certain pattern of heat) that corresponds to the XY distortion measurement of the distorted die to deform, correct or modify the XY dimension of the distorted die, and to control the bonding device 256 to bond the shaped die to a target wafer or die that is placed on the wafer chuck 251.

The thermal shaping of the distorted die by the light projection device 220 suffers from the time frame mismatch of bringing to the desired shape and the timeframe of fixating the shaped die in a desired target location (wafer or die) by bonding. This is caused by either the heatspreading of a thermal profile, e.g., the thermal XY profile, in the shaped die after the shaped die is released from the gripper 230 or the heatloss by contact between the shaped die and the target wafer or die. For example, bonding timeframe of a complete die at ambient conditions is about 0.5 to 1 second in maximum, during which the light projection device 220 does not project light onto (and does not heat equivalently) the shaped die and the shapeloss of the shaped die occurs. Improvement may be made by slowing the shapeloss by heatloss down and speeding up the bonding process.

The present disclosure introduces an intermediate step where the shaped die is placed (e.g., with its backside surface) on a sacrificial carrier substrate first. In an embodiment, the sacrificial carrier substrate can be made of a low thermal conductivity material, such as silicon oxide (SiOₓ) and silicon nitride (SiNₓ), which has a lower thermal conductivity than a silicon (Si) or germanium (Ge) wafer or die. Therefore, the heatloss (or heattransfer) of the shaped die to the sacrificial carrier substrate can be minimized and the shape of the shaped die can thus be fixed in time mechanically by the sacrificial carrier substrate.

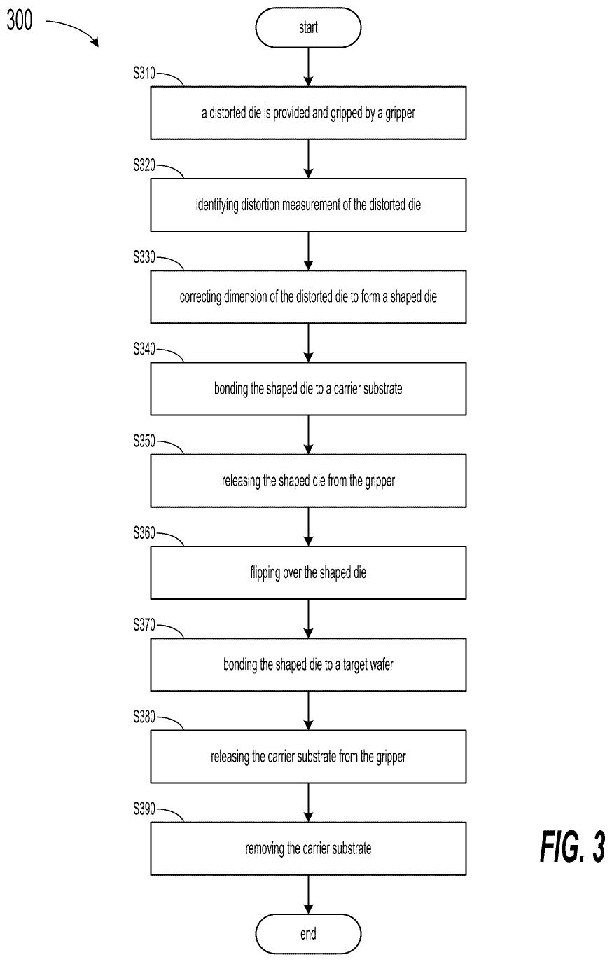

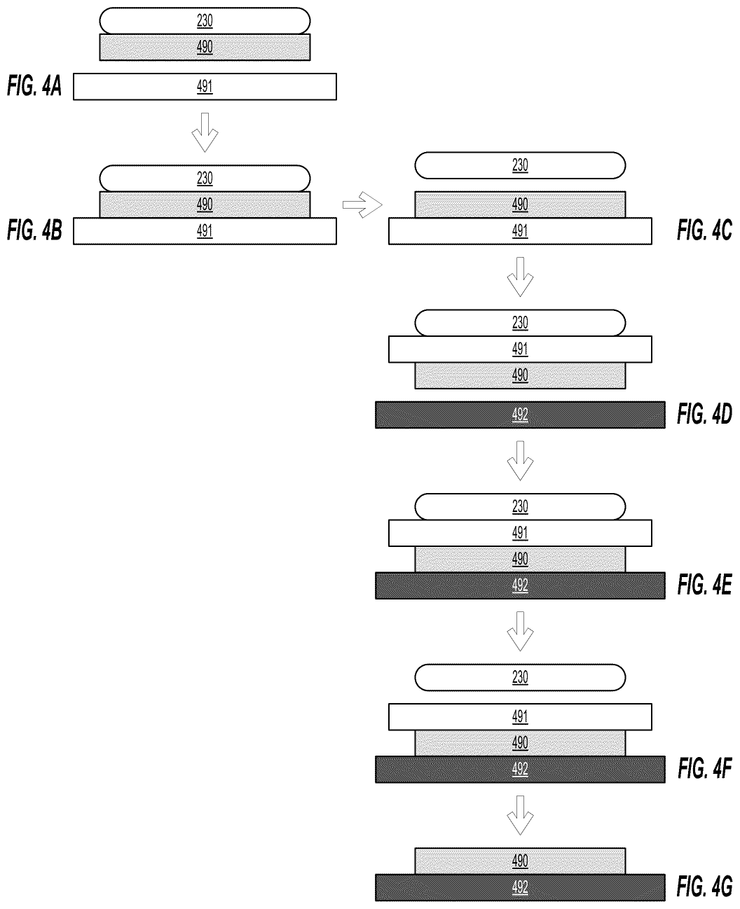

FIG. 3 is a flow chart of an exemplary method 300 that can bond a shaped die to a target semiconductor structure, e.g., a wafer or die, while the shape of the shaped die is fixed in time by a sacrificial carrier substrate, according to some embodiments of the present disclosure. In various embodiments, some of the steps of the method 300 shown can be performed concurrently or in a different order than shown, can be substituted by other method steps, or can be omitted. Additional method steps can also be performed as desired. Aspects of the method 300 can be implemented by a wafer processing system, such as the wafer processing system 200 illustrated in and described with respect to the preceding figures, e.g., FIG. 2. FIG. 4 is a schematic diagram illustrating the wafer processing system 200 implementing the method 300 according to some embodiments of the present disclosure. The method 300 starts with step S310, at which a die that is to be reshaped/distorted/deformed can be provided. For example, a distorted die 490 can be provided and gripped by the gripper 230, to be bonded to a sacrificial carrier substrate 491, as shown in FIG. 4A. In an embodiment, the distorted die 490 can be provided by singulating a distorted semiconductor structure, e.g., the semiconductor structures 190B-190F. The method 300 can proceed to step S320.

At step S320, the distorted die 490 can be measured to identify an XY distortion measurement of the distorted die 490. For example, the controller 240 can be used to control the distortion measurement device 210 to measure the distorted die 490 to identify the XY distortion measurement of the distorted die 490. The method 300 can proceed to step S330.

At step S330, the dimension of the distorted die 490 can be deformed, corrected or modified to form a shaped die 490. For example, the controller 240 can be used to control the light projection device 220 to project a certain pattern of light onto the distorted die 490 (equivalently, generating and applying a certain pattern of heat to the distorted die 490) according to the distortion measurement of the distorted die 490 to correct or modify the dimension of the distorted die 490 to form the shaped die 490. In an embodiment, the controller 240 can control the light projection units of the light projection device 220 independently to generate different intensities of light (accordingly, different temperatures of heat) that correspond to the XY distortion measurement of the distorted die 490. Accordingly, the distorted die 490 can be heated in different regions that correspond to the certain pattern of heat, which corresponds to the XY distortion measurement of the distorted die 490, and the dimension of the distorted die 490 can thus be corrected or modified to form the shaped die 490. The method 300 can proceed to step S340.

At step S340, the shaped die 490, which is gripped by the gripper 230, can be bonded to the sacrificial carrier substrate 491, as shown in FIG. 4B. For example, the carrier substrate 491 can be placed on the wafer chuck 251, and the controller 240 can be used to control the bonding device 225 to bond the shaped die 490, which is gripped by the gripper 230, to the carrier substrate 491. In an embodiment, the carrier substrate 491 can be made of a low thermal conductivity material, e.g., silicon oxide (SiOₓ) and silicon nitride (SiNₓ), which has lower thermal conductivity than the shaped die 490, which is made of silicon (Si) or germanium (Ge). Therefore, the heatloss (or heattransfer) of the shaped die 490 to the sacrificial carrier substrate 491 can be minimized and the shape of the shaped die 490 can thus be fixed in time mechanically by the sacrificial carrier substrate 491. The method 300 can proceed to step S350.

At step S350, the shaped die 490, which is bonded to the sacrificial carrier substrate 491, can be released from the gripper 230, as shown in FIG. 4C. For example, the controller 240 can be used to control the gripper 230, e.g., by stopping creating the negative pressure inside the hose and the vacuum head of the vacuum gripper 230, to release the shaped die 490, which is bonded to the sacrificial carrier substrate 491 and the shape of which is fixed in time mechanically by the sacrificial carrier substrate 491 at ambient temperature and conditions. The method 300 can proceed to step S360.

At step S360, the shaped die 490 can be flipped over and the carrier substrate 491, which is bonded to the shaped die 490, can be gripped by the gripper 230, for the shaped die 490 to be bonded to a target wafer (or die) 492, as shown in FIG. 4D. For example, the controller 240 can be used to control the robot 257 to flip the shaped die 490 over and to control the gripper 230 to grip the carrier substrate 491. The method 300 can proceed to step S370.

At step S370, the shaped die 490 can be bonded to the target wafer 492, as shown in FIG. 4E. For example, the controller 240 can be used to control the bonding device 256 to bond the shaped die 490, the shape of which is fixed in time mechanically by the carrier substrate 491, to the target wafer 492. Accordingly, the electrical connections, e.g., contact pads, of both the shaped die 490 and the target wafer 492 can be aligned with each other. The method 300 can proceed to step S380.

At step S380, the carrier substrate 491 can be released from the gripper 230, as shown in FIG. 4F. For example, the controller 240 can be used to control the gripper 230, e.g., by stopping creating the negative pressure inside the hose and the vacuum head of the vacuum gripper 230, to release the carrier substrate 491, which is bonded to the shaped die 490 to freeze the shape of the shaped die 490 mechanically at ambient temperature and conditions. The method 300 can proceed to step S390.

At step S390, the sacrificial carrier substrate 491 can be removed, as shown in FIG. 4G. For example, the controller 240 can be used to control the polishing device 255 to polish and remove the sacrificial carrier substrate 491. As another example, the sacrificial carrier substrate 491 can also be removed by a laser process.

The thermal shaping of a distorted die (or wafer) in order to form a shaped die, such as the shaped die 490, relies on creating a light profile (equivalently, a temperature profile) in the lateral direction (XY). Due to the lateral heat conduction, the natural tendency is that this temperature profile will even out to an even or uniform temperature. The present disclosure provides means to impose and maintain a light profile (and, accordingly, a temperature profile) applied to a die accurate enough and long enough to create the desired shape and size for the contact pads on both components aligned during die to die (or die to wafer) bonding. Various implementations can be realized, and a characteristic of the present disclosure is the integration of a light projection device with a gripper that can pick up, hold and place a (singulated) die that may be distorted. In an embodiment, the light projection device can have a plurality of light projection units that are arranged in a matrix. Therefore, the light projection device can keep on projecting the (singulated) die with a certain pattern of light (and, accordingly, keeping on heating the (singulated) die with a certain pattern of heat) while the semiconductor structure holding device 230 is holding (e.g., the gripper 230 is gripping) the die and maintaining the desired shape and size of the die until the die is bonded to a sacrificial carrier substrate and/or a target die or wafer.

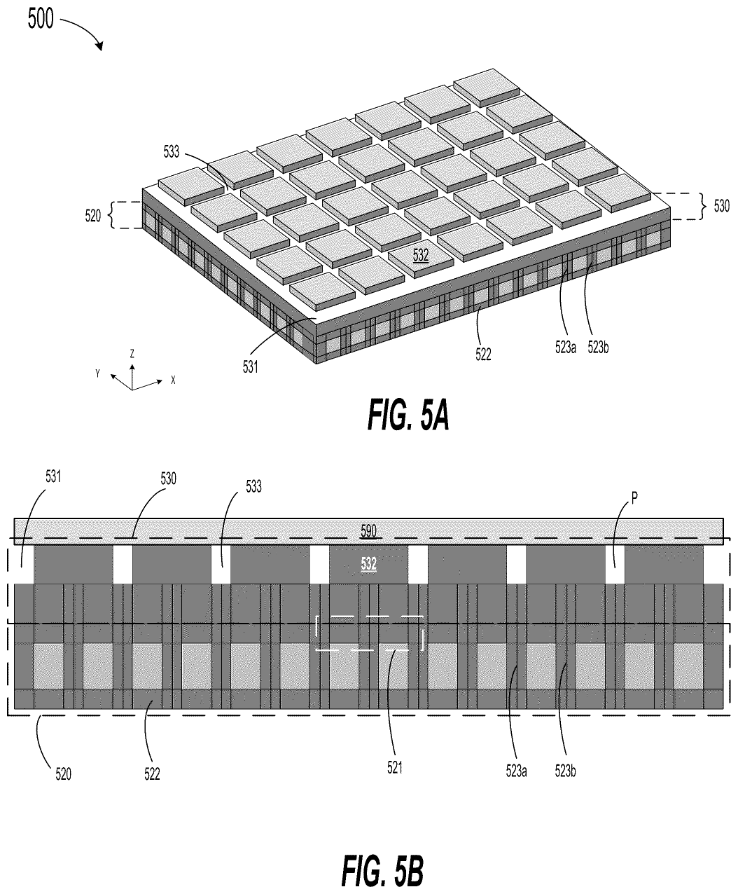

FIG. 5A is a schematic diagram of an exemplary apparatus 500 that includes a light projection device 520 (e.g., the light projection device 220) and a gripper (or a gripper of plate) 530 (e.g., the gripper 230) that are integrated with each other according to some embodiments of the present disclosure. FIG. 5B is a side view of the apparatus 500. In an embodiment, the gripper 530 can be configured to grip a (singulated, distorted) die 590 (shown in FIG. 5B), e.g., the distorted die 490, that is disposed thereon, and the light projection device 520 can be configured to generate a certain pattern of light (or, equivalently, a certain thermal XY pattern or profile), which can be projected onto the gripper 530 and applied to the singulated distorted die 590 to deform, correct or modify the dimension (e.g., XY distortion) of the distorted die 590 to form a shaped die.

In an embodiment, the gripper 530 can include a vacuum gripper. In operation, a negative pressure P can be created by a vacuum pump (not shown) and introduced through a hose (not shown) via a gripper hole 531 to fill channels or trenches 533 to cause suction cups or foam pads 532 to stick to the surface of the distorted die 590. In an embodiment, the foam pads 532 can be arranged in a matrix (e.g., 5×5, 5×7, etc.). In another embodiment, the foam pads 532 can be separated from one another, e.g., by the trenches 533. Therefore, the heat transferred to one of the foam pads 532 does not affect and is not affected by the remaining foam pads 532.

As the light generated by the light projection device 520 can be projected onto the gripper 530 and the corresponding heat thus generated can be transferred through the gripper 530 and applied to the distorted die 590, the gripper 530 can be made of a material that has heat conductivity high enough to transfer heat from itself to the distorted die 590 disposed on the gripper 530, but low enough to minimize lateral flow of heat. The lateral heat conduction may blur the XY-temperature pattern. For example, the gripper 530 may be made of aluminum nitride (AlN) or siliconized silicon carbide (SiSiC). For a die size of 25 mm×35 mm in width and length, the gripper 530 may be 2.5 mm in total thickness and the foam pads 532 arranged in a 5×7 matrix may be 0.35 mm in thickness and less than 5 mm×5 mm in width and length. In some embodiments, each of the foam pads 532 may be as small as 2 mm×2 mm in width and length in order to get enough XY resolution in the temperature (distortion) pattern.

In an embodiment, the light projection device 520 can include a plurality of light projection units 521 that are arranged in a matrix, each of light projection units 521 corresponding to one of the foam pads 532. The light projection device 520 can be configured to generate a certain pattern of light, and a certain pattern of heat thus generated accordingly can be transferred through the gripper 530 and applied to the distorted die 590. Accordingly, the light projection units 521 can have an arrangement corresponding to the certain pattern of light (equivalently, the certain pattern of heat) and be controlled independently, e.g., by the controller 240, to generate different temperature ranges of heat. For example, the light projection units 521 can be arranged in a matrix (e.g., 5×5, 5×7, etc.). Accordingly, the distorted die 590 can be heated in different regions that correspond to the certain pattern of heat, which is equivalent to the certain pattern of light that corresponds to the XY distortion measurement of the distorted die 590, and the (XY) dimension of the distorted die 590 can thus be corrected or modified.

The size and shape matching of two dies (or one die and one wafer) that have to be bonded will rely on precise and accurate temperature control. For a typical die size of 26 mm×33 mm in width and length, a 1K deviation will result in a size mismatch of ca 100 nm, and a 100 mK mismatch will result in a size mismatch of ca 10 nm, and so on. Therefore, the desired heat profile (and the desired temperature profile as well) will need to be superimposed on a carefully controlled base (or reference) temperature. In an embodiment, the base of the light projection device 520 can be placed on top of a well-designed heat sink 522 that can be maintained to a well-chosen reference temperature (e.g., 20° C.). In an embodiment, the light projection device 520 can also include a plurality of leads or legs (e.g., made of copper), e.g., first and second copper legs 523a and 523b, that are configured to electrically couple the heat sink 522 to the light projection units 521. In an embodiment, the first and second copper legs 523a and 523b can be 1.5 mm in length.

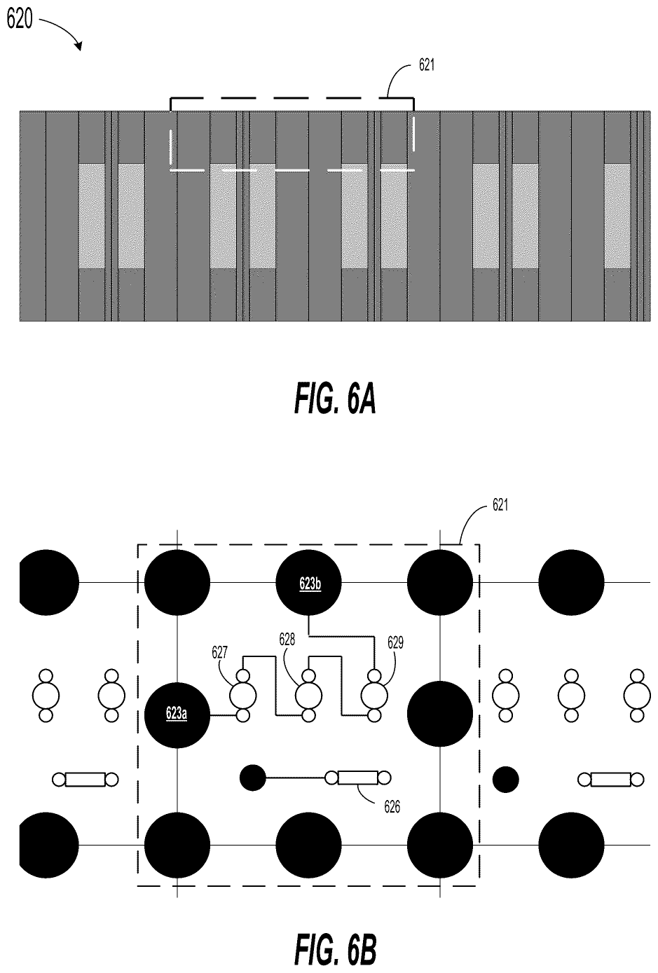

FIGS. 6A and 6B are a side view and a circuit diagram of an exemplary light projection device 620, e.g., the light projection device 520, respectively, according to some embodiments of the present disclosure. The light projection device 620 can include a plurality of light projection units 621, e.g., the light projection units 521, that are arranged in a matrix (e.g., 5×5, 5×7, etc.). In an embodiment, the light projection units 621 can provide localized light, and thus localized heat, to the gripper 530 such that the gripper 530 in different regions (e.g., at different foam pads 532), and the distorted die 590 in different regions as well, can be heated to different temperatures (i.e., the certain pattern of heat), and, as a result, the dimension of the distorted die 590 can be corrected or modified.

As shown in FIGS. 6A and 6B, each of the light projection units 621 can include one or more light sources, e.g., first to third light sources 627-629, that receive currents and generate light. In an embodiment, the first to third light sources 627-629 can be connected in parallel. In another embodiment, the first to third light sources 627-629 can be connected in series, as shown in FIG. 6B. For example, the second light source 628 can be serially connected between the first light source 627 and the third light source 629, one end of the first light source 627 that is not connected to the second light source 628 can be connected to a first lead or leg (e.g., made of copper) 623a, and one end of the third light source 629 that is not connected to the second light source 628 can be connected to a second lead or leg (e.g., made of copper) 623b.

Additionally, each of the light projection units 621 can further include a temperature sensor 626, acting as a measuring resistor, that is configured to sense the temperature of the light projection unit 621, so that the balance between thus generated heat by the light sources (i.e., the first to third light sources) 627-629 and removed heat by a gripper integrated therewith, e.g., the gripper 530, can be established to generate the desired stable temperature pattern. In an embodiment, the temperature sensor 626 can be physical (like a positive temperature coefficient (PTC) or a negative temperature coefficient (NTC) thermistor) or via infra-red imaging. Therefore, the precise temperature per heating unit 621 in the (e.g., 5×5 or 5×7) heating matrix (e.g., the light projection device 620) needs to be determined, e.g., by the controller 240 based on the distortion measurement of the distorted die 590 identified by the distortion measurement device 210, to create the desired local expansion to the distorted die 590. The dimension of the distorted die 590 will have to be corrected or modified such that all of the contact pads on the respective die will meet and make accurate electrical contact. Typically, this match should be better than 20 nm rms.

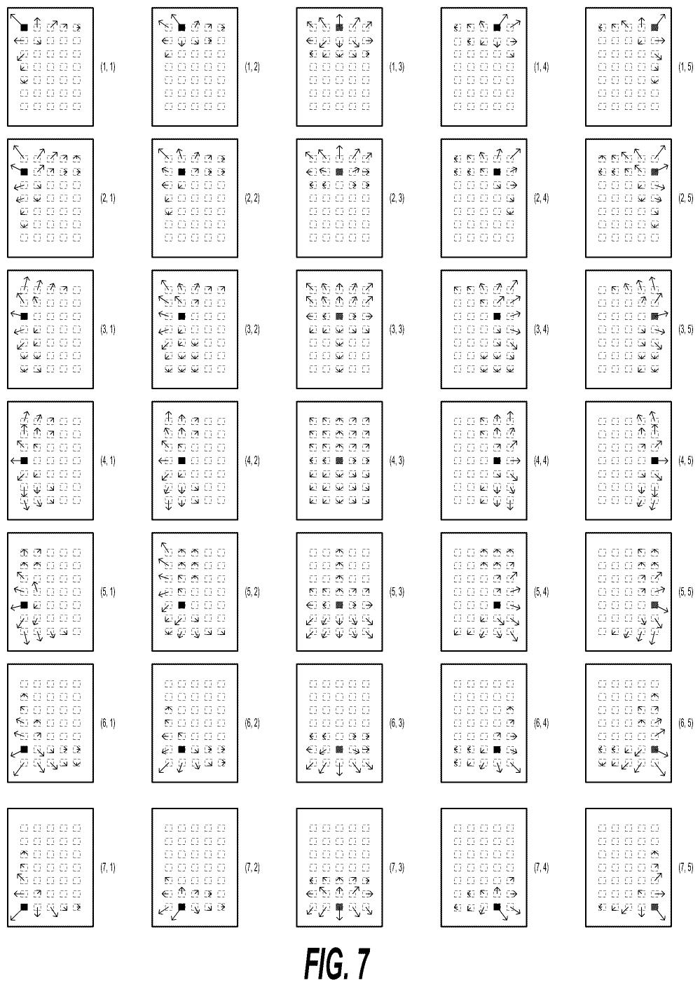

FIG. 7 illustrates how the light and heat generated by each of a plurality of light projection units (e.g., the light projection units 621) of a light projection device (e.g., the light projection device 620) that are arranged in a matrix (e.g., a 5×7 matrix), distorts or causes displacement to a die according to some embodiments of the present disclosure. The dimension of the die, e.g., the distorted die 590, can be corrected or modified based on a combination (e.g., a linear combination) of the distortions created by the individual light projection units 621. For example, in a 5×7 light projection (heating) matrix (e.g., the light projection units 521 shown in FIGS. 5A and 5B), the distortion field of the die caused by any of the light projection units [1,1], [1, 2], . . . , [2, 1], . . . , [7, 4] and [7, 5], e.g., the light projection unit [2, 3], can be determined. This will be a vector field of displacements {u, v} for each location on the die. The displacement fields (called displacement primitives) caused by different light projection units will be different from each other. For example, the displacement field caused by the light projection [1, 4] will be different than that caused by the light projection [2, 3].

In operation, metrology equipment, e.g., the (XY) distortion measurement device 210 can be controlled, e.g., by the controller 240, to measure a die that may be distorted, e.g., the distorted die 590, to identify a distortion measurement, e.g., an XY distortion measurement, of the distorted die 590, and the light projection device 620 (the light projection units 621) can be controlled to generate a certain pattern of light (and a corresponding certain pattern of heat) based on the distortion measurement, which is transferred through the gripper 630 and applied to the distorted die 590. In an embodiment, the displacement fields caused by the light projection units 621 can be summed linearly, and the temperature (and the heat generated) per light projection unit 621 can be seen as a weight function for the displacement field per light projection unit 621. For example, the displacement field (i.e., displacement primitive) caused by the heating unit [x, y] is {u, v}_{[x, y]}, and the total distortion [x, y] will be the sum (over XY) of dT[x, y]×{u, v}_{[x, y]}, where dT(x, y) can be solved via a matrix inversion operation, e.g., a least squares method.

The displacements caused by the individual light projection units 621 can be estimated theoretically, or can be measured or preferably be simulated by finite element method (FEM) to take specific mechanical construction in account.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. An apparatus, comprising:
a semiconductor structure holding device configured to hold a semiconductor structure; and
a light projection device configured to generate a certain pattern of light,
wherein the light projection device is integrated with the semiconductor structure holding device such that when the semiconductor structure holding device is holding the semiconductor structure, the certain pattern of light generated by the light projection device is projected onto the semiconductor structure holding device and a corresponding certain pattern of heat is generated and transferred through the semiconductor structure holding device and applied to the semiconductor structure.

2. The apparatus of claim 1, wherein the semiconductor structure holding device is a gripper.

3. The apparatus of claim 2, wherein the gripper is a vacuum gripper.

4. The apparatus of claim 2 wherein the gripper includes aluminum nitride (AlN).

5. The apparatus of claim 2, wherein the gripper includes siliconized silicon carbide (SiSiC).

6. The apparatus of claim 1, wherein the light projection device includes a plurality of light projection units that are controlled to generate light independently.

7. The apparatus of claim 6, wherein the light projection units are arranged in a matrix.

8. The apparatus of claim 6, wherein at least one of the light projection units includes one or more laser devices.

9. The apparatus of claim 6, wherein at least one of the light projection units includes a digital light processor.

10. The apparatus of claim 6, wherein at least one of the light projection units includes an array of light pipes.

11. The apparatus of claim 6, wherein the at least one of the light projection units further includes a temperature sensor that is configured to sense a temperature of the at least one of the light projection units.

12. The apparatus of claim 11, wherein the temperature sensor includes a thermistor.

13. The apparatus of claim 6, wherein the light projection device further includes a heat sink that is thermally coupled to the light projection units.

14. A method, comprising:
generating a certain pattern of light such that a corresponding certain pattern of heat is applied to a first semiconductor structure to shape the first semiconductor structure; and
bonding a first surface of the shaped first semiconductor structure to a carrier substrate,
wherein the carrier substrate has a lower thermal conductivity than the first semiconductor structure.

15. The method of claim 14, wherein the carrier substrate includes silicon oxide (SiOₓ) or silicon nitride (SiNₓ).

16. The method of claim 14, further comprising:
forming a light absorption layer on a first semiconductor structure,
wherein generating the certain pattern of light includes generating the certain pattern of light such that the corresponding certain pattern of heat is applied to the light absorption layer formed on the first semiconductor structure to shape the first semiconductor structure.

17. The method of claim 14, further comprising:
bonding a second surface of the shaped first semiconductor structure to a second semiconductor structure; and
removing the carrier substrate.

18. The method of claim 14, further comprising:
providing a plurality of light projection units that are configured to generate light independently; and
controlling the light projection units to generate the certain pattern of light.

19. The method of claim 18, wherein each of the light projection units generates heat that causes a corresponding displacement field to the semiconductor structure, and the certain pattern of heat is applied based on a combination of the displacement fields caused by the heating units.

20. The method of claim 14, further comprising:
providing a semiconductor structure holding device that is configured to hold the first semiconductor structure; and
controlling the semiconductor structure holding device to hold the first semiconductor structure.
